(19) United States
(12) Patent Application Publication
(10) Pub. No.: US 2024/0260395 A1
(43) Pub. Date: Aug. 1, 2024

(54) DISPLAY DEVICE

(71) Applicant: Sharp Display Technology Corporation, Kameyama City, Mie (JP)

(72) Inventors: Mayuko SAKAMOTO, Kameyama City, Mie (JP); Ikuo NINOMIYA, Kameyama City, Mie (JP); Tokio TAGUCHI, Kameyama City, Mie (JP)

(21) Appl. No.: 18/560,470

(22) PCT Filed: Jun. 23, 2021
(86) PCT No.: PCT/JP2021/023786

§ 371 Date: Nov. 13, 2023

(51) Int. Cl. H10K 59/80; H10K 77/10; H10K 102/00

(52) U.S. Cl. CPC H10K 59/872; H10K 59/8722; H10K 77/111; H10K 2102/311

(57) ABSTRACT

A flexible display panel including a display region including a pair of flat portions held in a flat manner and a bendable portion disposed between the pair of flat portions and held in a bendable manner and a frame region provided in a periphery of the display region, a support substrate supporting the display panel in a flat manner, and a housing supporting the support substrate are provided, and in the display region, the display panel and the support substrate are not fixed to each other and a gap is formed between the support substrate and the housing.

### TECHNICAL FIELD

The disclosure relates to a display device.

### BACKGROUND ART

In recent years, self-luminous organic electroluminescence (hereinafter also referred to as EL) display devices using organic EL elements have attracted attention as display devices that can replace liquid crystal display devices. As the organic EL display device, a display panel having a structure (a layered body) in which an organic EL element, a variety of films, and the like are layered on a flexible resin substrate has been adopted, and an organic EL display device which can be repeatedly folded, a so-called foldable display has been proposed.

In the foldable display, since it is necessary to maintain flexibility, a rigid member such as an inflexible (rigid) cover cannot be provided on a surface. Thus, the flexible display panel may be locally deformed by a drop impact or the like when an object is dropped on the surface of the flexible display panel or when the foldable display itself is dropped. When a crack or the like occurs in an inorganic film of a thin film transistor (hereinafter, also referred to as “TFT”) layer constituting the display panel due to the local deformation of the display panel, a bright spot, a black spot (a point defect) or the like occurs in the foldable display to cause a display defect. As described above, the foldable display has a problem of low impact resistance against dropping.

With respect to the above problem, a variety of methods for reducing the possibility of occurrence of the display defect have been studied. For example, PTL 1 discloses a foldable display including an impact absorption layer provided between a flexible display layer (a first display region, a second display region, and a third display region) and an inflexible first support substrate supporting the first display region and between the flexible display layer and an inflexible second support substrate supporting the second display region. The impact absorption layer includes a metal film for improving the impact resistance of the foldable display.

### CITATION LIST

### Patent Literature

PTL 1: WO 2020/203584

### SUMMARY

### Technical Problem

In the foldable display described in PTL 1, the metal film constituting the impact absorption layer is adhered to the entirety of a display region as a part (one layer) of the layered body constituting the flexible display layer (the display panel). Thus, for example, in a case where a large point impact such as pen drop in which a pen tip having a small ball diameter is dropped on the display panel is received, the metal film may not be sufficiently bent and the point impact may not be sufficiently alleviated.

In addition, in the foldable display described in PTL 1, although a first and a second support substrates supporting the first and the second display regions (non-bendable region, range X illustrated in FIG. 1), respectively, are provided, a support substrate is not present on the lower side of the third display region (bendable region, range Y illustrated in FIG. 1) located between the first display region and the second display region. Thus, when the large point impact such as the pen drop is applied to the bendable region, the display panel may be locally deformed in the vicinity of the bendable region. In addition, even in a case where a relatively thick adhesive layer is present between the first display region and the first support substrate and between the second display region and second support substrate, when the large point impact is applied to the non-bendable region, the adhesive layer having flexibility is locally deformed, and thus the display panel may be locally deformed also in the non-bendable region.

Furthermore, in the foldable display described in PTL 1, since the panel configuration is largely different between the non-bendable region and the bendable region, there is a concern about problems such as undulation of the display panel and folding habit at the time of bending in the bendable region. When these problems are attempted to be solved, the flexibility of the display panel may not be maintained.

The disclosure has been made in view of the above, and an object of the disclosure is to achieve both the impact resistance against the large point impact and the flexibility of the display panel.

### Solution to Problem

In order to achieve the above object, a display device according to the disclosure includes a flexible display panel including a display region including a pair of flat portions held in a flat manner and a bendable portion disposed between the pair of flat portions and held in a bendable manner and a frame region provided in a periphery of the display region, a support substrate supporting the display panel in a flat manner, and a housing supporting the support substrate, in which in the display region, the display panel and the support substrate are not fixed to each other and a gap is formed between the support substrate and the housing.

### Advantageous Effects of Disclosure

According to the disclosure, both impact resistance against a large point impact and flexibility of a display panel can be achieved.

### BRIEF DESCRIPTION OF DRAWINGS

FIG. 1 is a perspective view illustrating a deployed state of an organic EL display device according to a first embodiment of the disclosure.

FIG. 2 is a plan view illustrating a deployed state of the organic EL display device according to the first embodiment of the disclosure.

FIG. 3 is a cross-sectional view, taken along a line III-III in FIG. 2, illustrating a deployed state of the organic EL display device according to the first embodiment of the disclosure.

FIG. 4 is a plan view illustrating a deployed state of a first modification example of the organic EL display device according to the first embodiment of the disclosure, and is a view corresponding to FIG. 2.

FIG. 5 is an enlarged cross-sectional view, taken along a line V-V in FIG. 4, illustrating a folded state in which the first modification example of the organic EL display device according to the first embodiment of the disclosure is folded in a U-shape.

FIG. 6 is a plan view illustrating a deployed state of a second modification example of the organic EL display device according to the first embodiment of the disclosure, and is a view corresponding to FIG. 2.

FIG. 7 is an enlarged cross-sectional view, taken along a line VII-VII in FIG. 6, illustrating a folded state in which the second modification example of the organic EL display device according to the first embodiment of the disclosure is folded in the U-shape, and is a view corresponding to FIG. 5.

FIG. 8 is a plan view illustrating a deployed state of a third modification example of the organic EL display device according to the first embodiment of the disclosure, and is a view corresponding to FIG. 2.

FIG. 9 is an enlarged cross-sectional view, taken along a line IX-IX in FIG. 8, illustrating a folded state in which the third modification example of the organic EL display device according to the first embodiment of the disclosure is folded in the U-shape, and is a view corresponding to FIG. 5.

FIG. 10 is a plan view of the display region of the organic EL display device according to the first embodiment of the disclosure.

FIG. 11 is a cross-sectional view of the display region of the organic EL display device according to the first embodiment of the disclosure.

FIG. 12 is an equivalent circuit diagram of a TFT layer constituting the organic EL display device according to the first embodiment of the disclosure.

FIG. 13 is a cross-sectional view of an organic EL layer included in the organic EL display device according to the first embodiment of the disclosure.

FIG. 14 is a cross-sectional view illustrating a deployed state of an organic EL display device according to a second embodiment of the disclosure, and is a view corresponding to FIG. 3.

FIG. 15 is a cross-sectional view illustrating a deployed state of a modification example of the organic EL display device according to the second embodiment of the disclosure, and is a view corresponding to FIG. 3.

FIG. 16 is a cross-sectional view illustrating a deployed state of an organic EL display device according to a third embodiment of the disclosure, and is a view corresponding to FIG. 3.

FIG. 17 is an enlarged cross-sectional view illustrating a folded state in which the organic EL display device according to the third embodiment of the disclosure is folded in the U-shape, and is a view corresponding to FIG. 5.

FIG. 18 is an enlarged cross-sectional view illustrating a folded state in which the organic EL display device according to the third embodiment of the disclosure is folded in a droplet shape, and is a view corresponding to FIG. 5.

FIG. 19 is a cross-sectional view illustrating a deployed state of an organic EL display device according to a fourth embodiment of the disclosure, and is a view corresponding to FIG. 3.

FIG. 20 is a plan view illustrating a deployed state of a support substrate constituting the organic EL display device according to the fourth embodiment of the disclosure.

### DESCRIPTION OF EMBODIMENTS

Embodiments of a technique according to the disclosure will be described below in detail with reference to the drawings. Note that the technique according to the disclosure is not limited to the embodiments to be described below.

### First Embodiment

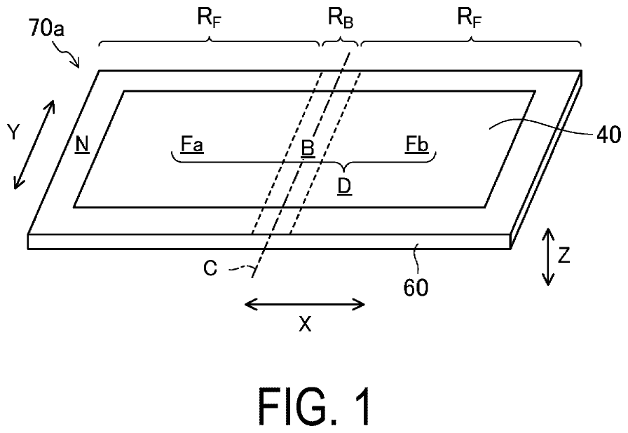

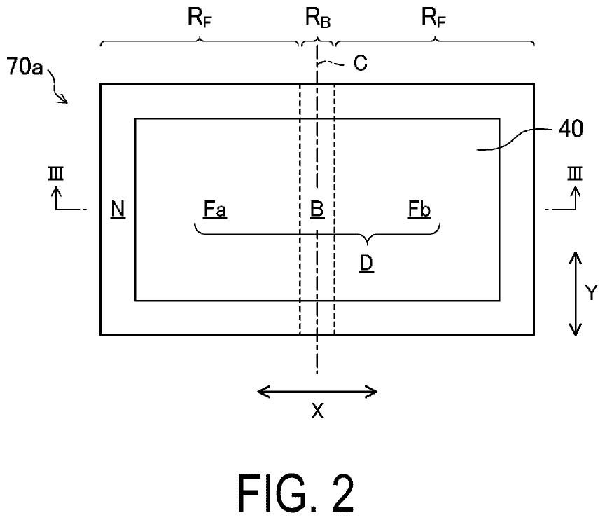

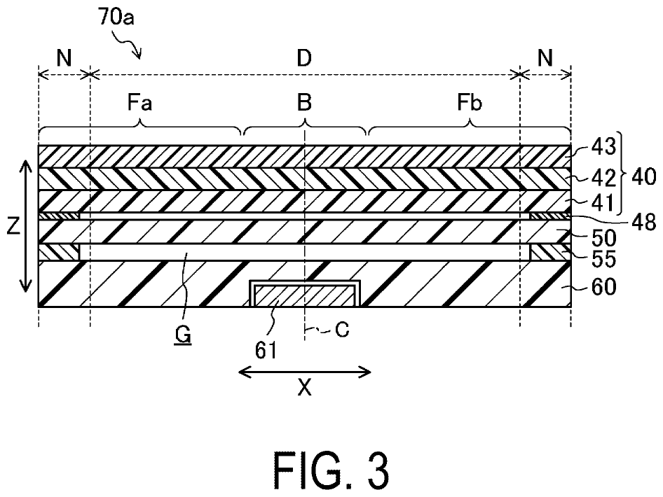

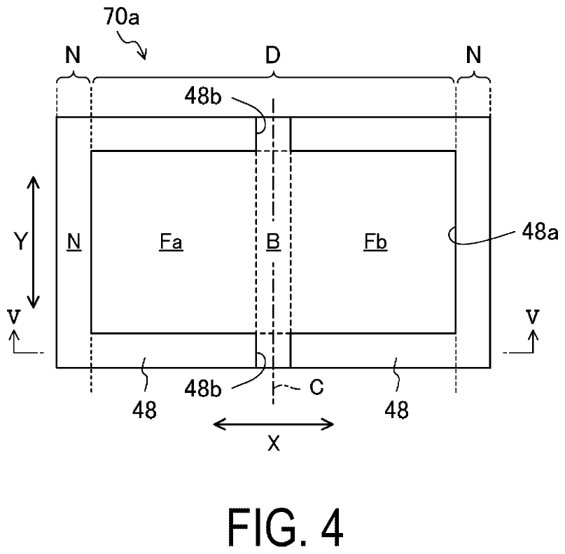

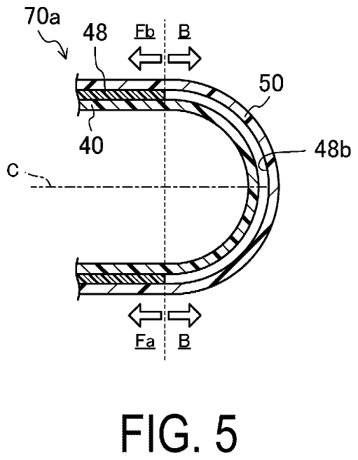

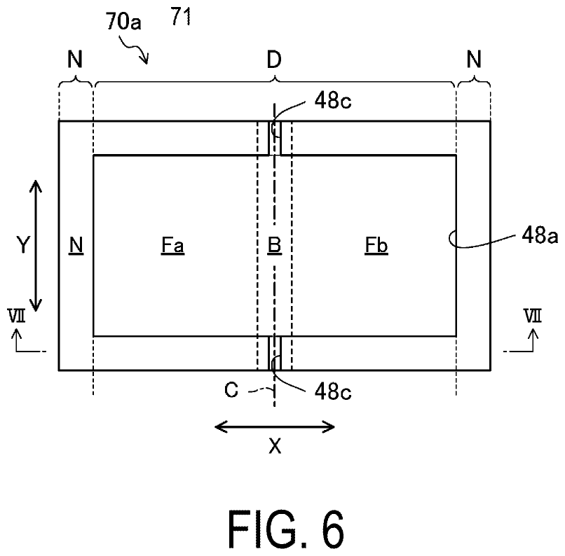

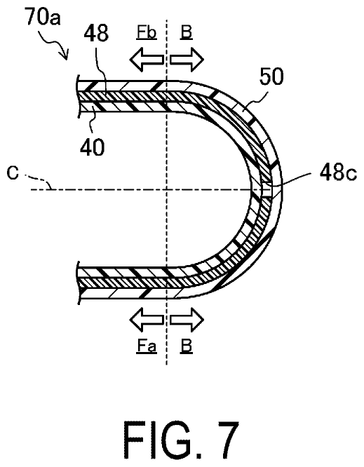

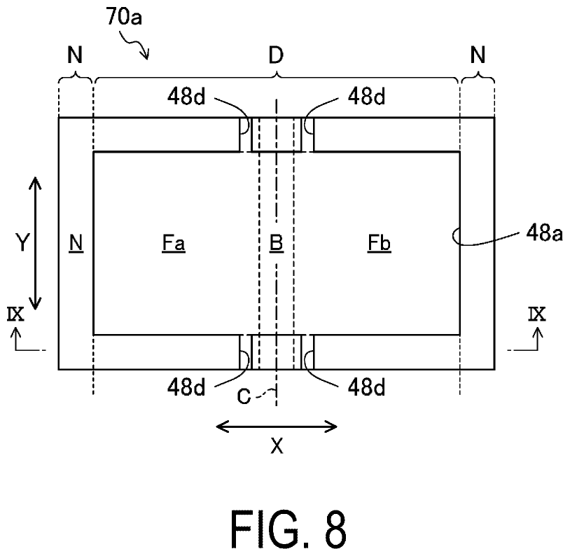

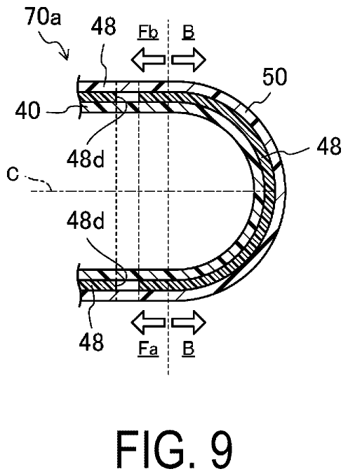

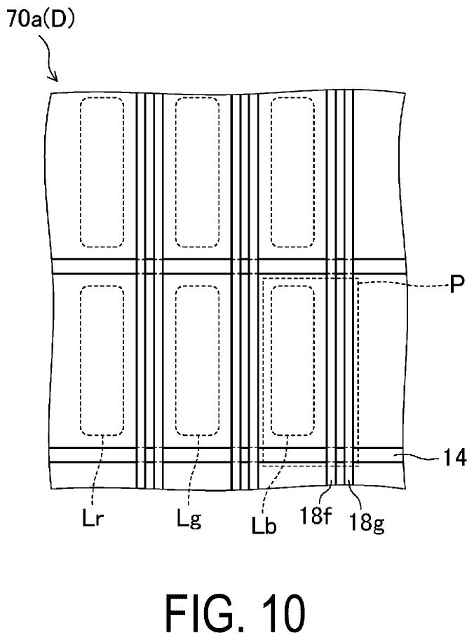

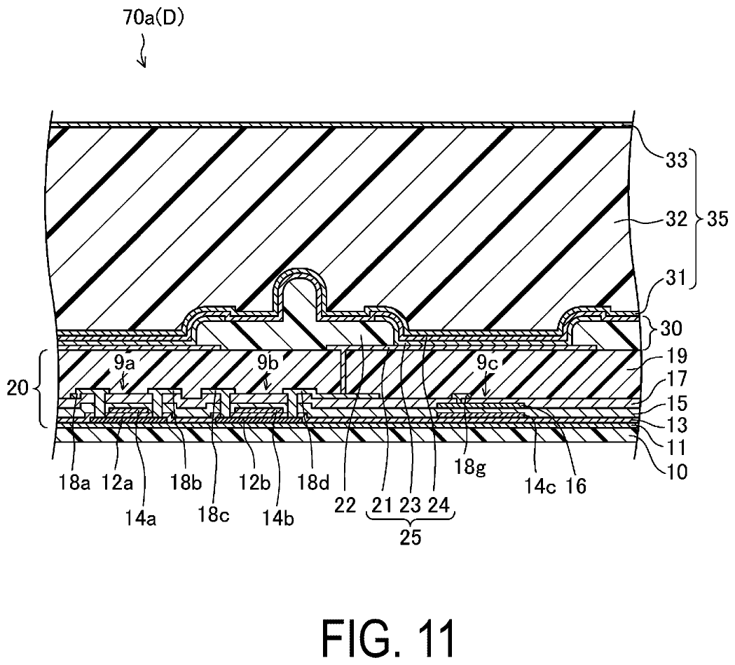

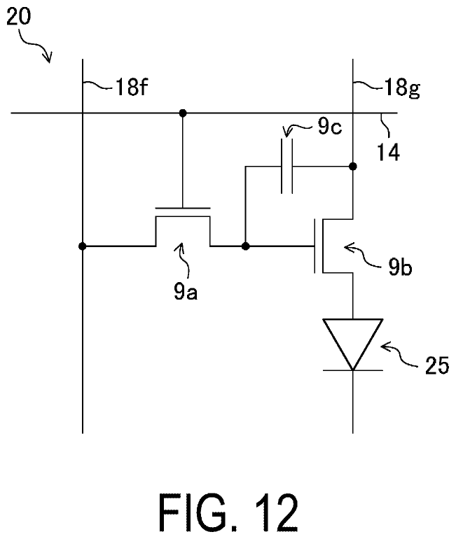

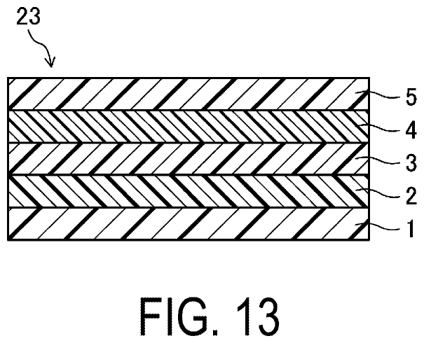

FIG. 1 to FIG. 13 illustrate a first embodiment of a display device and a method for manufacturing the display device according to the disclosure. Note that, in each of the following embodiments, an organic EL display device including an organic EL element will be exemplified as a display device including a light-emitting element. FIG. 1 is a perspective view illustrating a deployed state of an organic EL display device 70a according to the present embodiment. FIG. 2 is a plan view illustrating the deployed state of the organic EL display device 70a. FIG. 3 is a cross-sectional view, taken along a line III-III in FIG. 2, illustrating a deployed state of the organic EL display device 70a. FIG. 4 is a plan view illustrating the deployed state of a first modification example of the organic EL display device 70a, and is a view corresponding to FIG. 2. FIG. 5 is an enlarged cross-sectional view, taken along a line V-V in FIG. 4, illustrating a folded state in which the first modification example of the organic EL display device 70a is folded in a U-shape. FIG. 6 is a plan view illustrating a deployed state of a second modification example of the organic EL display device 70a, and is a view corresponding to FIG. 2. FIG. 7 is an enlarged cross-sectional view, taken along a line VII-VII in FIG. 6, illustrating a folded state in which the second modification example of the organic EL display device 70a is folded in a U-shape, and is a view corresponding to FIG. 5. FIG. 8 is a plan view illustrating a deployed state of a third modification example of the organic EL display device 70a, and is a view corresponding to FIG. 2. FIG. 9 is an enlarged cross-sectional view, taken along a line IX-IX in FIG. 8, illustrating a folded state in which the third modification example of the organic EL display device 70a is folded in the U-shape, and is a view corresponding to FIG. 5. FIG. 10 is a plan view of a display region D of the organic EL display device 70a. FIG. 11 is a cross-sectional view of the display region D of the organic EL display device 70a. FIG. 12 is an equivalent circuit diagram of a TFT layer 20 constituting the organic EL display device 70a. FIG. 13 is a cross-sectional view of an organic EL layer 23 constituting the organic EL display device 70a. Note that, in the organic EL display device 70a, a direction X parallel to a substrate surface of an organic EL display panel 40 described below, a direction Y perpendicular to the direction X and parallel to the substrate surface of the organic EL display panel 40, and a direction Z perpendicular to the direction X and the direction Y are defined.

As illustrated in FIG. 1 to FIG. 3, the organic EL display device 70a includes at least an organic EL display panel 40, a support substrate 50, and a housing 60.

As illustrated in FIG. 1 and FIG. 2, the organic EL display panel 40 includes, for example, the display region (active area) D provided in a rectangular shape and configured to display an image, and a frame region (non-display region) N provided in a frame-like shape in a periphery of the display region D. Note that, in the present embodiment, the display region D having the rectangular shape is exemplified, but the rectangular shape includes a substantial rectangular shape such as a shape whose sides are arc-shaped, a shape whose corners are arc-shaped, and a shape in which a part of a side has a notch. Note that one end of the frame region N in the X direction in FIG. 1 to FIG. 3 is provided with a terminal portion (not illustrated) in which a plurality of terminals are arrayed.

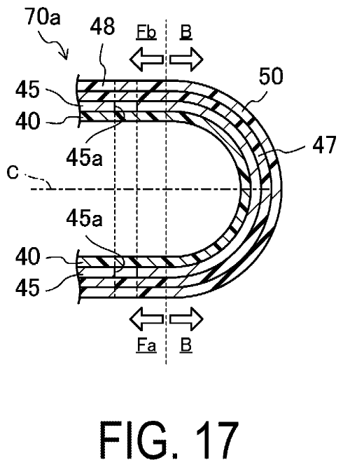

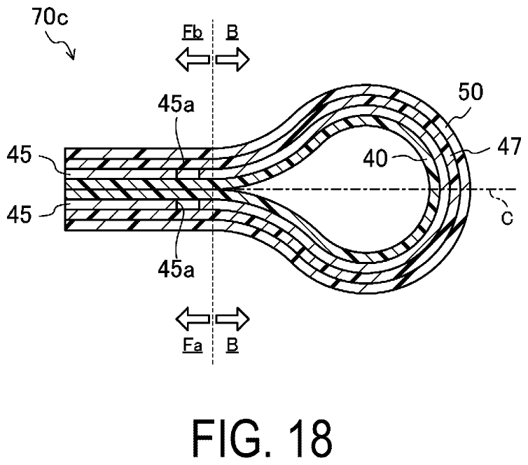

As illustrated in FIG. 1 to FIG. 3, the display region D includes a pair of flat portions (a part of a non-bendable region R_{F} described later) Fa and Fb held in a flat manner (flat surface) and a bendable portion (a part of a bendable region R_{B} described later) B disposed between the pair of flat portions Fa and Fb and held in a bendable manner. As illustrated in FIG. 1 and FIG. 2, in the bendable portion B (bendable region R_{B}), a bending axis (bending center) C that is bendable to 180° (U-shape) is possible so that the pair of flat portions Fa and Fb face each other is provided to extend in the direction Y. Note that, in the side view, a bent shape of the organic EL display panel 40 is not limited to the U-shape (see FIG. 5, FIG. 7, FIG. 9, and FIG. 17), and may be, for example, a droplet shape (see FIG. 18).

As illustrated in FIG. 1 and FIG. 2, the organic EL display panel 40 includes the bendable region R_{B} along the bending axis C and a pair of the non-bendable regions R_{F} and R_{F} located at both ends of the bendable region R_{B} in the direction X. As illustrated in FIG. 1 and FIG. 2, the bendable region R_{B} is a region linearly extending along the bending axis C (direction Y) and including the bendable portion B (a part of the display region D) and both end portions (a part of the frame region N) in the direction Y of the bendable portion B. The non-bendable region R_{F} is a region other than the bendable region R_{B}, and is a rectangular region in a plan view including the pair of flat portions Fa and Fb (parts of the display region D) and each peripheral portion (a part of the frame region N) of a respective one of the pair of flat portions Fa and Fb.

The size of the organic EL display panel 40 is, for example, about 10 cm in width (vertical direction in FIG. 2, length in the direction Y), about 18 cm in length (horizontal direction in FIG. 1 to FIG. 3, length in the direction X), and about several hundred μm in thickness (vertical direction in FIG. 1 and FIG. 3, length in the direction Z). A specific configuration of the organic EL display panel 40 will be described below.

As illustrated in FIG. 3, the support substrate 50 is provided on a back surface (lower side in FIG. 3) of the organic EL display panel 40, and is configured to support the organic EL display panel 40 in a flat manner. The support substrate 50 is flexible and includes a flexible metal film. The support substrate 50 may be formed of (only) a single flexible metal film. The metal film is preferably a member having a large elastic modulus such as a metal thin film, and is formed of, for example, a material containing at least one selected from stainless steel, titanium, aluminum, and copper. The thickness (length in the direction Z) of the metal film is, for example, 20 μm and more and 45 μm or less, and preferably 25 μm or more and 35 μm or less. The elastic modulus of the metal film layer is, for example, 60 GPa or more and 210 GPa or less.

The support substrate 50 further includes a flexible resin film, and may be a layered body (metal film/resin film) including a resin film and a metal film. In addition, the support substrate 50 may be a layered body (metal film/adhesive layer/resin film) in which an adhesive layer is provided between the metal film and the resin film. The resin film is formed of, for example, an acrylonitrile-butadiene-styrene copolymer (ABS) resin, a polystyrene (PS) resin, a polycarbonate (PC) resin, or a polymethyl methacrylate (PMMA) resin. The thickness (length in the direction Z) of the resin film is, for example, 25 μm and more and 300 μm or less, and preferably 50 μm or more and 150 μm or less. The elastic modulus of the resin film is, for example, 30 MPa or more and 5 GPa or less.

In addition to the metal film and the resin film, the support substrate 50 may further include an elastomer layer formed of an elastomer (for example, silicon rubber), and may be a layered body including the elastomer layer, the resin film, and the metal film. The support substrate 50 may be formed of (only) a single elastomer layer. The thickness (length in the direction Z) of the elastomer layer is, for example, 100 μm or more and 500 μm or less. The elastic modulus of the elastomer layer is, for example, 1 MPa or more and 10 MPa or less.

The thickness (in a case of the layered body, the thickness of the entire layered body) of the support substrate 50 is, for example, 20 μm and more and 500 μm or less, and preferably 30 μm or more and 300 μm or less. From the viewpoint of keeping the shape of the organic EL display panel 40 flat and preventing undulation, the elastic modulus of the support substrate 50 is preferably relatively large and is, for example, 1 MPa or more and 210 GPa or less, and preferably 30 MPa or more and 200 GPa or less.

As illustrated in FIG. 3, in the organic EL display device 70a, the support substrate 50 is formed of one substrate over the entirety of the organic EL display panel 40. In other words, the support substrate 50 has the same configuration in the non-bendable region R_{F} (flat portions Fa and Fb) and in the bendable region R_{B} (bendable portion B). That is, the support substrate 50 is also provided (present) on the lower side of the bendable region R_{B} (a portion overlapping the bendable portion B in a plan view). As a result, the support substrate 50 on the lower side of the bendable portion B is bent in response to the point impact to the bendable portion B or its vicinity, and thus the local deformation of the organic EL display panel 40 is suppressed. In addition, in the bendable region R_{B}, problems such as undulation of the organic EL display panel 40 and folding habit at the time of bending are also reduced.

As illustrated in FIG. 1 and FIG. 3, the housing 60 is a box (case) that accommodates the organic EL display panel 40 and the support substrate 50. As illustrated in FIG. 3, the housing 60 is provided on the lower side of the support substrate 50, and is configured to support the support substrate 50. The housing 60 is inflexible (rigid) and is formed of a rigid member such as a metal or a resin. As illustrated in FIG. 3, in the housing 60, a thickness of a portion overlapping the bendable portion B in a plan view is thin, and a hinge mechanism 61 is provided in the thin portion. By the hinge mechanism 61, the organic EL display device 70a functions as a foldable display that is foldable. Note that the hinge mechanism 61 is not particularly limited as long as it is a bendable mechanism. The housing 60 may be provided with a battery, a circuit substrate, and the like.

In the organic EL display device 70a having the above-described configuration, for example, the organic EL display panel 40 and the support substrate 50 are accommodated in the housing 60 having the hinge mechanism 61, and the organic EL display device 70a is deformable between a deployed state (see FIG. 1 to FIG. 3, FIG. 4, FIG. 6, and FIG. 8) in which one flat portion Fa, the bendable portion B, and the other flat portion Fb of the organic EL display panel 40 are disposed on the same plane and a folded state (see FIG. 5, FIG. 7, and FIG. 9) in which the bendable portion B is bent and the pair of flat portions Fa and Fb are disposed to face each other.

As illustrated in FIG. 3, in the organic EL display device 70a, the organic EL display panel 40 and the support substrate 50 are not fixed to each other in the entirety of the display region D. Thus, even when the large point impact such as the pen drop is applied, the organic EL display panel 40 is gently deformed. A non-fixed region between the organic EL display panel 40 and the support substrate 50 may not be the entirety of the display region D and may be at least a partial region of the display region D. However, from a viewpoint of the impact resistance, the non-fixed region is preferably provided in the entirety of the display region D.

In the display region D (preferably, its entirety thereof), the organic EL display panel 40 and the support substrate 50 may be simply not fixed to each other, and a gap (air gap, space) need not be formed therebetween, or the gap may be formed therebetween.

In addition, as illustrated in FIG. 3, in the organic EL display device 70a, a gap (air gap) G is formed between the support substrate 50 and the housing 60 in the entirety of a region (hereinafter also simply referred to as “display region D”) overlapping the display region D in a plan view. The gap G is a space defined by the support substrate 50 and the housing 60. That is, as illustrated in FIG. 3, the support substrate 50 and the housing 60 are not fixed to each other in the entirety of the display region D. As a result, the support substrate 50 can be sufficiently bent toward the lower side (in the direction in which the gap G is present), and thus even the large point impact can be alleviated. Note that the gap G may not be the entirety of the display region D and may be at least a part of the display region D. However, from a viewpoint of the impact resistance, the non-fixed region is preferably provided in the entirety of the display region D.

The gap G may be filled with a gas such as air or an inert gas, or may contain a gas such as air that may be contained in a normal manufacturing process. The gap G may be a completely closed space (a space where air or the like cannot enter and exit) or may be an incompletely closed space (a space where air or the like can enter and exit).

The thickness (length in the direction Z) of the gap G is, for example, about 300 μm, and is preferably 200 μm or more and 750 μm or less, and more preferably 300 μm or more and 450 μm or less from a viewpoint that the support substrate 50 is sufficiently bent and even the large point impact is alleviated.

As illustrated in FIG. 3, examples of a method of forming the gap G include a method of fixing the support substrate 50 and the housing 60 via, for example, a fixing member 55 or the like in a region overlapping the frame region N in a plan view (hereinafter, also simply referred to as “frame region N”). That is, as illustrated in FIG. 3, the support substrate 50 and the housing 60 are fixed to each other in the frame region N. Specifically, the support substrate 50 and the housing 60 are fixed to each other only at a portion overlapping the frame region N in a plan view.

Examples of the fixing member 55 include a resin or a metal frame provided in a frame shape along the periphery of the display region D so as to overlap the frame region N in a plan view, and a resin or a metal block provided in a rectangular shape, a circular shape, an elliptical shape, or the like in a plan view. For example, a fixing member 55 having a frame shape may be provided along the entire periphery of the organic EL display panel 40 along the frame region N. In this case, the gap G defined by the fixing member 55 having the frame shape, the support substrate 50, and the housing 60 is formed in the above-described completely closed space. In addition, a fixing member 55 having a block shape may be disposed in an island shape along the frame region N. In this case, the gap G defined by the fixing member 55 having the block shape, the support substrate 50, and the housing 60 is formed in the above-described incompletely closed space.

The thickness (length in the direction Z) of the fixing member 55 is not particularly limited, and may be appropriately determined according to the thickness of the gap G described above. The support substrate 50 and the housing 60 may be fixed to the fixing member 55 by adhesive fixing by providing an adhesive layer (an optical clear adhesive (OCA), an adhesive tape, a sponge cushion, or the like), or by screwing fixing using a screw or the like. In a case where the gap G is formed between the support substrate 50 and the housing 60 by adopting the adhesive fixing using a thick adhesive tape, a sponge cushion, or the like or the screw fixing, the fixing member 55 need not be used.

Similarly to the above, as illustrated in FIG. 3, the organic EL display panel 40 and the support substrate 50 are fixed to each other in the frame region N. Specifically, the organic EL display panel 40 and the support substrate 50 are fixed to each other only in the frame region N.

The organic EL display panel 40 and the support substrate 50 may be fixed to each other by the adhesive fixing by providing the adhesive layer (the optical clear adhesive (OCA), the adhesive tape, the sponge cushion, or the like), or by the screwing fixing using the screw or the like. When the adhesive fixing is adopted, as illustrated in FIG. 3, an adhesive layer 48 having a frame shape along the periphery of the display region D may be provided between the organic EL display panel 40 and the support substrate 50 so as to overlap the frame region N in a plan view. In this case, the adhesive layer 48 is provided along the entire periphery of the organic EL display panel 40 along the frame region N. In other words, the adhesive layer 48 is provided with an opening in a portion overlapping the display region D in a plan view. That is, the adhesive layer 48 includes an opening (hereinafter also referred to as “display region opening”) 48a (see FIGS. 4, 6, and 8) formed in the portion overlapping the display region D in a plan view. The thickness (length in the direction Z) of the adhesive layer 48 may be relatively thick, and is preferably 15 μm or more and 100 μm or less. The elastic modulus of the adhesive layer 48 is preferably 2.0×10⁴ [Pa] or more and 1.0×10⁶ [Pa] or less, and more preferably 3.0×10⁴ [Pa] or more and 1.5×10⁵ [Pa] or less.

As described above, as illustrated in FIG. 3, in the organic EL display device 70a, in a portion (a portion corresponding to the frame region N) overlapping the frame region N in a plan view, the upper face of the support substrate 50 is fixed to the lower face of the organic EL display panel 40 and the lower face of the support substrate 50 is fixed to the upper face of the housing 60. On the other hand, in the entirety of a portion (portion corresponding to the display region D) overlapping the display region D in a plan view, the support substrate 50 is not fixed to any of the organic EL display panel 40 and the housing 60, and the gap G is present on the lower side of the support substrate 50. As a result, in the organic EL display device 70a, the impact resistance against the large point impact is improved while maintaining excellent flexibility.

### First Modification Example of First Embodiment

As illustrated in FIG. 4 and FIG. 5, the adhesive layer 48 may also be provided with an opening in a portion overlapping the frame region N in a plan view. That is, the adhesive layer 48 may include, in addition to the display region opening 48a, a pair of openings (hereinafter also referred to as “frame region openings”) 48b and 48b formed in portions, respectively, where the bendable region R_{B} extending along the bendable portion B and the frame region N overlap each other in a plan view. In this case, as illustrated in FIG. 4, the adhesive layer 48 is divided (separated) into two parts by the pair of frame region openings 48b and 48b and the two parts are disposed to be separated from each other. In FIG. 4, the organic EL display panel 40 is omitted. In FIG. 6, the housing 60 is omitted.

In the first modification example, as illustrated in FIG. 4, each of the pair of frame region openings 48b and 48b is formed in the entirety of a portion where the frame region N and the bendable portion B (bendable region R_{B}) overlap each other in a plan view, and is provided in a rectangular shape in a plan view. That is, as illustrated in FIG. 4 and FIG. 5, the organic EL display panel 40 and the support substrate 50 are not fixed to each other in a portion overlapping the entirety of the bendable region R_{B} including the bendable portion B in a plan view. As a result, even when there is a difference in the amount of deflection due to the difference in elastic modulus between the organic EL display panel 40 and the support substrate 50, the organic EL display panel 40 and the support substrate 50 are less likely to affect each other. In this case, the adhesive layer 48 may be thin, and is, for example, about 2 μm or more and about 50 μm or less.

### Second Modification Example of First Embodiment

As illustrated in FIG. 6 and FIG. 7, the adhesive layer 48 may include, in addition to the display region opening 48a, a pair of frame region openings 48c and 48c formed in a portion where the bendable region R_{B} extending along the bendable portion B and the frame region N overlap each other in a plan view. In this case, as illustrated in FIG. 6, the adhesive layer 48 is divided (separated) into two parts by the pair of frame region openings 48c and 48c, respectively, and the two parts are disposed to be separated from each other. In FIG. 6, the organic EL display panel 40 is omitted. In FIG. 7, the housing 60 is omitted.

As illustrated in FIG. 6 and FIG. 7, in the second modification example, the pair of frame region openings 48c and 48c are different in shape, size, and the like from the pair of frame region openings 48b and 48b in the first modification example. Specifically, as illustrated in FIG. 6, each of the pair of frame region openings 48c and 48c is formed in a slit shape extending along the bending axis C (direction Y) of the bendable portion B (bendable region R_{B}). That is, as illustrated in FIG. 6 and FIG. 7, the organic EL display panel 40 and the support substrate 50 are not fixed to each other in a portion of the bendable region R_{B} including the bendable portion B, which overlaps a region in the vicinity of the bending axis C in a plan view. As a result, even when there is a difference in the amount of deflection due to the difference in elastic modulus between the organic EL display panel 40 and the support substrate 50, the organic EL display panel 40 and the support substrate 50 are less likely to affect each other. In this case, the adhesive layer 48 may be thin, and is, for example, about 2 μm or more and about 50 μm or less.

### Third Modification Example of First Embodiment

As illustrated in FIG. 8 and FIG. 9, the adhesive layer 48 may include, in addition to the display region opening 48a, a pair of frame region openings 48d and 48d formed in portions overlapping a pair of the frame regions N and N provided in peripheries of the pair of flat portions Fa and Fb, respectively, in a plan view. In this case, as illustrated in FIG. 8, the adhesive layer 48 is divided (separated) into four parts by the pair of frame region openings 48d and 48d, and the four parts are disposed to be separated from each other. In FIG. 8, the organic EL display panel 40 is omitted. In FIG. 9, the housing 60 is omitted.

As illustrated in FIG. 8 and FIG. 9, in the third modification example, the pair of frame region openings 48d and 48d are different in position, number, and the like from the pair of frame region openings 48c and 48c in the second modification example. Specifically, as illustrated in FIG. 8, in the adhesive layer 48, two pairs (four in total) of frame region openings 48d and 48d are formed in portions closer to the bendable portion B in the pair of frame regions N and N provided in the peripheries of the pair of flat portions Fa and Fb, respectively. More specifically, each of the pair of frame region openings 48d and 48d is formed in the slit shape extending along the bending axis C (direction Y) of the bendable portion B similarly to the second modification example in the vicinity of the bendable region R_{B} (bendable portion B) which is a portion where the non-bendable region R_{F} and the frame region N overlap each other in a plan view. That is, as illustrated in FIG. 8 and FIG. 9, the organic EL display panel 40 and the support substrate 50 are not fixed to each other in portions of the non-bendable region R_{F} including the pair of flat portions Fa and Fb, which overlap regions in the vicinity of both ends in the direction X of the bendable region R_{B} including the bendable portion B in a plan view. As a result, even when there is a difference in the amount of deflection due to the difference in elastic modulus between the organic EL display panel 40 and the support substrate 50, the organic EL display panel 40 and the support substrate 50 are less likely to affect each other. In this case, the adhesive layer 48 may be thin, and is, for example, about 2 μm or more and about 50 μm or less.

As illustrated in FIG. 3, the organic EL display panel 40 includes a flexible display layer 41, a function layer 42, and a cover 43, which are layered in this order.

As illustrated in FIG. 10, a plurality of subpixels P are disposed in a matrix shape in the display region D of the flexible display layer 41 (organic EL display panel 40). In addition, as illustrated in FIG. 10, in the display region D, for example, a subpixel P including a red light-emitting region Lr for displaying a red color, a subpixel P including a green light-emitting region Lg for displaying a green color, and a subpixel P including a blue light-emitting region Lb for displaying a blue color are provided adjacent to one another. Note that one pixel is configured by, for example, three adjacent subpixels P including the red light-emitting region Lr, the green light-emitting region Lg, and the blue light-emitting region Lb in the display region D.

As illustrated in FIG. 11, in the flexible display layer 41 (organic EL display panel 40), the organic EL display device 70a includes a resin substrate layer 10 provided as a base substrate, the TFT layer 20 provided on the resin substrate layer 10, an organic EL element layer 30 provided as a light-emitting element layer on the TFT layer 20, and a sealing film 35 provided on the organic EL element layer 30.

The resin substrate layer 10 is formed, for example, of a polyimide resin.

As illustrated in FIG. 11, the TFT layer 20 includes a base coat film 11 provided on the resin substrate layer 10, a plurality of first TFTs 9a, a plurality of second TFTs 9b, and a plurality of capacitors 9c provided on the base coat film 11, and a flattening film 19 provided on each of the first TFTs 9a, each of the second TFTs 9b, and each of the capacitors 9c. Here, as illustrated in FIG. 11, on the TFT layer 20, the base coat film 11, semiconductor layers 12a and 12b, a gate insulating film 13, a first wiring line layer such as a gate line 14 (see FIG. 10), gate electrodes 14a and 14b, and a lower conductive layer 14c, a first interlayer insulating film 15, an upper conductive layer 16, a second interlayer insulating film 17, a second wiring line layer such as a source line 18f (see FIG. 10), source electrodes 18a and 18c, drain electrodes 18b and 18d, and a power source line 18g, and the flattening film 19 are layered in this order on the resin substrate layer 10. In addition, as illustrated in FIG. 10 and FIG. 12, on the TFT layer 20, a plurality of the gate lines 14 are provided extending in parallel to one another in the lateral direction in the figures. In addition, as illustrated in FIG. 10 and FIG. 12, on the TFT layer 20, a plurality of the source lines 18f are provided extending in parallel to one another in the longitudinal direction in the figures. In addition, as illustrated in FIG. 10 and FIG. 12, on the TFT layer 20, a plurality of the power source lines 18g are provided extending in parallel to one another in the longitudinal direction in the figures. Note that, as illustrated in FIG. 10, each of the power source lines 18g is provided in a state of being adjacent to each of the source lines 18f. In the TFT layer 20, as illustrated in FIG. 12, each of the subpixels P is provided with the first TFT 9a, the second TFT 9b, and the capacitor 9c.

For example, each of the base coat film 11, the gate insulating film 13, the first interlayer insulating film 15, and the second interlayer insulating film 17 is composed of a single-layer film or a layered film of an inorganic insulating film of silicon nitride, silicon oxide, silicon oxynitride, or the like.

The first TFT 9a and the second TFT 9b are p-type TFTs in which the semiconductor layers 12a and 12b (described later) are doped with a dopant such as boron, for example.

As illustrated in FIG. 12, the first TFT 9a is electrically connected to the corresponding gate line 14 and source line 18f in each of the subpixels P. Additionally, as illustrated in FIG. 11, the first TFT 9a includes a semiconductor layer 12a, a gate insulating film 13, a gate electrode 14a, a first interlayer insulating film 15, a second interlayer insulating film 17, and a source electrode 18a and a drain electrode 18b, which are sequentially provided on the base coat film 11. Here, as illustrated in FIG. 11, the semiconductor layer 12a is provided in an island shape on the base coat film 11, and has, for example, a channel region, a source region, and a drain region. In addition, as illustrated in FIG. 11, the gate insulating film 13 is provided so as to cover the semiconductor layer 12a. Additionally, as illustrated in FIG. 11, the gate electrode 14a is provided on the gate insulating film 13 so as to overlap the channel region of the semiconductor layer 12a. Additionally, as illustrated in FIG. 11, the first interlayer insulating film 15 and the second interlayer insulating film 17 are sequentially provided so as to cover the gate electrode 14a. Additionally, as illustrated in FIG. 11, the source electrode 18a and the drain electrode 18b are separated from each other on the second interlayer insulating film 17. Additionally, as illustrated in FIG. 11, the source electrode 18a and the drain electrode 18b are electrically connected to the source region and the drain region of the semiconductor layer 12a, respectively, via each contact hole formed in a layered film including the gate insulating film 13, the first interlayer insulating film 15, and the second interlayer insulating film 17.

As illustrated in FIG. 12, the second TFT 9b is electrically connected to the corresponding first TFT 9a and power source line 18g in each of the subpixels P. As illustrated in FIG. 11, the second TFT 9b includes the semiconductor layer 12b, the gate insulating film 13, the gate electrode 14b, the first interlayer insulating film 15, the second interlayer insulating film 17, and the source electrode 18c and the drain electrode 18d, which are provided in this order on the base coat film 11. Here, as illustrated in FIG. 11, the semiconductor layer 12b is provided in an island shape on the base coat film 11 and has, for example, a channel region, a source region, and a drain region. Additionally, as illustrated in FIG. 11, the gate insulating film 13 is provided so as to cover the semiconductor layer 12b. Additionally, as illustrated in FIG. 11, the gate electrode 14b is provided on the gate insulating film 13 so as to overlap the channel region of the semiconductor layer 12b. Additionally, as illustrated in FIG. 11, the first interlayer insulating film 15 and the second interlayer insulating film 17 are sequentially provided so as to cover the gate electrode 14b. Additionally, as illustrated in FIG. 11, the source electrode 18c and the drain electrode 18d are separated from each other on the second interlayer insulating film 17. Additionally, as illustrated in FIG. 11, the source electrode 18c and the drain electrode 18d are electrically connected to the source region and the drain region of the semiconductor layer 12b, respectively, via each contact hole formed in a layered film including the gate insulating film 13, the first interlayer insulating film 15, and the second interlayer insulating film 17.

Note that, in the present embodiment, the first TFT 9a and the second TFT 9b are exemplified as being of a top-gate type TFT, but the first TFT 9a and the second TFT 9b may be a bottom-gate type TFT.

As illustrated in FIG. 12, the capacitor 9c is electrically connected to the corresponding first TFT 9a and power source line 18g in each of the subpixels P. Here, as illustrated in FIG. 11, the capacitor 9c includes the lower conductive layer 14c, the first interlayer insulating film 15 provided to cover the lower conductive layer 14c, and the upper conductive layer 16 provided on the first interlayer insulating film 15 to overlap the lower conductive layer 14c. Note that, as illustrated in FIG. 11, the upper conductive layer 16 is electrically connected to the power source line 18g via a contact hole formed in the second interlayer insulating film 17.

The flattening film 19 has a flat surface in the display region D, and is formed of an organic resin material such as a polyimide resin, for example.

As illustrated in FIG. 11, the organic EL element layer 30 includes a plurality of organic EL elements 25 as a plurality of light-emitting elements arrayed in a matrix shape corresponding to the plurality of subpixels P.

As illustrated in FIG. 11, the organic EL element 25 includes a first electrode 21 provided on the flattening film 19 in each of the subpixels P, the organic EL layer 23 provided in each of the subpixels P on the first electrode 21, and a second electrode 24 provided on the organic EL layer 23 commonly to the plurality of subpixels P.

As illustrated in FIG. 11, the first electrode 21 is electrically connected to the drain electrode 18d of the second TFT 9b of each of the subpixels P via a contact hole formed in the flattening film 19. In addition, the first electrode 21 has a function of injecting holes (positive holes) into the organic EL layer 23. In addition, the first electrode 21 is preferably formed of a material with a high work function to improve the efficiency of hole injection into the organic EL layer 23. Here, examples of a material constituting the first electrode 21 include metal materials such as silver (Ag), aluminum (Al), vanadium (V), cobalt (Co), nickel (Ni), tungsten (W), gold (Au), titanium (Ti), ruthenium (Ru), manganese (Mn), indium (In), ytterbium (Yb), lithium fluoride (LiF), platinum (Pt), palladium (Pd), molybdenum (Mo), iridium (Ir), and tin (Sn). Examples of the material constituting the first electrode 21 may include alloys such as astatine (At)/astatine oxide (AtO₂). Furthermore, the material constituting the first electrode 21 may be an electrically conductive oxide, for example, tin oxide (SnO), zinc oxide (ZnO), indium tin oxide (ITO), or indium zinc oxide (IZO). In addition, the first electrode 21 may be formed by layering a plurality of layers formed of any of the materials described above. Note that examples of compound materials having a high work function include indium tin oxide (ITO) and indium zinc oxide (IZO). Furthermore, a peripheral end portion of the first electrode 21 is covered with an edge cover 22 provided in a lattice shape commonly to the plurality of subpixels P. Here, examples of a material constituting the edge cover 22 include a positive-working photosensitive resin such as a polyimide resin, an acrylic resin, a polysiloxane resin, and a novolac resin.

As illustrated in FIG. 13, the organic EL layer 23 includes a hole injection layer 1, a hole transport layer 2, a light-emitting layer 3, an electron transport layer 4, and an electron injection layer 5 that are sequentially provided on the first electrode 21.

The hole injection layer 1 is also referred to as an anode electrode buffer layer, and has a function of reducing an energy level difference between the first electrode 21 and the organic EL layer 23 to thereby improve the efficiency of hole injection into the organic EL layer 23 from the first electrode 21. Here, examples of materials constituting the hole injection layer 1 include triazole derivatives, oxadiazole derivatives, imidazole derivatives, polyarylalkane derivatives, pyrazoline derivatives, phenylenediamine derivatives, oxazole derivatives, styrylanthracene derivatives, fluorenone derivatives, hydrazone derivatives, and stilbene derivatives.

The hole transport layer 2 has a function of improving the efficiency of hole transport from the first electrode 21 to the organic EL layer 23. Here, examples of materials constituting the hole transport layer 2 include porphyrin derivatives, aromatic tertiary amine compounds, styrylamine derivatives, polyvinylcarbazole, poly-p-phenylenevinylene, polysilane, triazole derivatives, oxadiazole derivatives, imidazole derivatives, polyarylalkane derivatives, pyrazoline derivatives, pyrazolone derivatives, phenylenediamine derivatives, arylamine derivatives, amine-substituted chalcone derivatives, oxazole derivatives, styrylanthracene derivatives, fluorenone derivatives, hydrazone derivatives, stilbene derivatives, hydrogenated amorphous silicon, hydrogenated amorphous silicon carbide, zinc sulfide, and zinc selenide.

The light-emitting layer 3 is a region where holes and electrons are injected from the first electrode 21 and the second electrode 24, respectively, and the holes and the electrons recombine, when a voltage is applied via the first electrode 21 and the second electrode 24. Here, the light-emitting layer 3 is formed of a material having high luminous efficiency. Moreover, examples of materials constituting the light-emitting layer 3 include metal oxinoid compounds (8-hydroxyquinoline metal complexes), naphthalene derivatives, anthracene derivatives, diphenylethylene derivatives, vinyl acetone derivatives, triphenylamine derivatives, butadiene derivatives, coumarin derivatives, benzoxazole derivatives, oxadiazole derivatives, oxazole derivatives, benzimidazole derivatives, thiadiazole derivatives, benzothiazole derivatives, styryl derivatives, styrylamine derivatives, bisstyrylbenzene derivatives, trisstyrylbenzene derivatives, perylene derivatives, perinone derivatives, aminopyrene derivatives, pyridine derivatives, rhodamine derivatives, aquidine derivatives, phenoxazone, quinacridone derivatives, rubrene, poly-p-phenylenevinylene, and polysilane.

The electron transport layer 4 has a function of facilitating migration of electrons to the light-emitting layer 3 efficiently. Here, examples of materials constituting the electron transport layer 4 include oxadiazole derivatives, triazole derivatives, benzoquinone derivatives, naphthoquinone derivatives, anthraquinone derivatives, tetracyanoanthraquinodimethane derivatives, diphenoquinone derivatives, fluorenone derivatives, silole derivatives, and metal oxinoid compounds, as organic compounds.

The electron injection layer 5 has a function of reducing an energy level difference between the second electrode 24 and the organic EL layer 23 to thereby improve the efficiency of electron injection into the organic EL layer 23 from the second electrode 24, and the electron injection layer 5 can lower the drive voltage of the organic EL element 25 by this function. Note that the electron injection layer 5 is also referred to as a cathode electrode buffer layer. Here, examples of materials constituting the electron injection layer 5 include inorganic alkaline compounds, such as lithium fluoride (LiF), magnesium fluoride (MgF₂), calcium fluoride (CaF₂), strontium fluoride (SrF₂), and barium fluoride (BaF₂), aluminum oxide (Al₂O₃), and strontium oxide (SrO).

As illustrated in FIG. 11, the second electrode 24 is provided to cover the organic EL layer 23 of each of the subpixels P and the edge cover 22. In addition, the second electrode 24 has a function of injecting electrons into the organic EL layer 23. In addition, the second electrode 24 is preferably formed of a material with a low work function to improve the efficiency of electron injection into the organic EL layer 23. Here, examples of materials constituting the second electrode 24 include silver (Ag), aluminum (Al), vanadium (V), cobalt (Co), nickel (Ni), tungsten (W), gold (Au), calcium (Ca), titanium (Ti), yttrium (Y), sodium (Na), ruthenium (Ru), manganese (Mn), indium (In), magnesium (Mg), lithium (Li), ytterbium (Yb), and lithium fluoride (LiF). The second electrode 24 may also be formed of an alloy such as magnesium (Mg)/copper (Cu), magnesium (Mg)/silver (Ag), sodium (Na)/potassium (K), astatine (At)/astatine oxide (AtO₂), lithium (Li)/aluminum (Al), lithium (Li)/calcium (Ca)/aluminum (Al), and lithium fluoride (LiF)/calcium (Ca)/aluminum (Al), for example. In addition, the second electrode 24 may be formed of electrically conductive oxide, for example, tin oxide (SnO), zinc oxide (ZnO), indium tin oxide (ITO), indium zinc oxide (IZO), or the like. In addition, the second electrode 24 may be formed by layering a plurality of layers formed of any of the materials described above. Note that examples of materials having a low work function include magnesium (Mg), lithium (Li), lithium fluoride (LiF), magnesium (Mg)/copper (Cu), magnesium (Mg)/silver (Ag), sodium (Na)/potassium (K), lithium (Li)/aluminum (Al), lithium (Li)/calcium (Ca)/aluminum (Al), and lithium fluoride (LiF)/calcium (Ca)/aluminum (Al).

As illustrated in FIG. 11, the sealing film 35 is provided on the organic EL element layer 30 to cover each of the organic EL elements 25. Here, as illustrated in FIG. 11, the sealing film 35 includes a first inorganic sealing film 31 provided to cover the second electrode 24, an organic sealing film 32 provided on the first inorganic sealing film 31, and a second inorganic sealing film 33 provided to cover the organic sealing film 32, and has a function of protecting the organic EL layer 23 from moisture, oxygen, and the like. Here, the first inorganic sealing film 31 and the second inorganic sealing film 33 are formed of an inorganic material such as, for example, silicon oxide (SiO₂), aluminum oxide (Al₂O₃), silicon nitride (SiNx (where x is a positive number)) such as trisilicon tetranitride (Si₃N₄), or silicon carbonitride (SiCN). The organic sealing film 32 is formed of an organic material such as an acrylic resin, a polyurea resin, a parylene resin, a polyimide resin, or a polyamide resin.

As illustrated in FIG. 3, the function layer 42 is provided on the flexible display layer 41 so as to cover the flexible display layer 41. Examples of the function layer 42 include a functional film having a various functions such as an optical compensation function, a touch panel sensor function, and a protection function. The function layer 42 has flexibility in order to ensure flexibility of the organic EL display panel. If necessary, the adhesive layer (OCA) may be provided between the flexible display layer 41 and the function layer 42.

As illustrated in FIG. 3, the cover 43 is provided on the function layer 42 so as to cover the function layer 42. The cover 43 protects the flexible display layer 41 (and the function layer 42). The cover 43 is flexible in order to ensure the flexibility of the organic EL display panel. The flexible cover 43 is formed of, for example, a UV-curable organosilicon resin. Specific examples of the cover 43 include a known window film that has been subjected to a hardcoating process. If necessary, the adhesive layer (OCA) may be provided between the function layer 42 and the cover 43.

The above-described organic EL display device 70a, in each of the subpixels P, inputs a gate signal to the first TFT 9a via the gate line 14 to turn on the first TFT 9a, writes a voltage corresponding to a source signal to the gate electrode 14b and the capacitor 9c of the second TFT 9b via the source line 18f, and supplies the organic EL layer 23 with a current from the power source line 18g defined based on the gate voltage of the second TFT 9b, whereby the light-emitting layer 3 of the organic EL layer 23 emits light to display an image. Note that, in the organic EL display device 70a, even when the first TFT 9a is turned off, the gate voltage of the second TFT 9b is held by the capacitor 9c. Thus, the light emission by the light-emitting layer 3 is maintained until the gate signal of the next frame is input.

### EXAMPLE

The disclosure will be described below based on examples. Note that the disclosure is not limited to the following examples, the following examples can be modified and changed based on the gist of the disclosure, and they are not intended to be excluded from the scope of the disclosure.

### Comparative Example 1

A flexible organic EL display panel was manufactured in which a flexible display layer, a function layer, and a cover were layered in order. By using the organic EL display device (foldable display) including only the flexible organic EL display panel, a drop impact test and a bending test were performed based on a method described below. As a result, according to the organic EL display device of a comparative example 1, the bending test was passed, but the drop impact test was failed because a point defect caused by breakage of the TFT layer occurred.

### Drop Impact Test

The flexible organic EL display panel was placed on a plastic underlayer (thickness was 50 mm). In this state, a ballpoint pen was dropped from a height 10 cm away from the panel surface so that a pen tip of the ballpoint pen dropped (pen drop) on the panel surface.

### Bending Test

### Test Preparation

The non-bendable region R_{F} of the flexible organic EL panel (see FIG. 1 and FIG. 2) was fixed to a fixing plate formed of plastic. A double-sided adhesive tape was used as a method for fixing to the fixing plate. The fixing plate may be formed of a metal, and may be fixed to the panel by using an adhesive, and in this case, the test result is less likely to be affected.

Subsequently, the organic EL panel fixed to the fixing plate was set in a bending test apparatus (manufactured by Yuasa System Co., Ltd., product number: DMLHP) via the fixing plate so that a bending radius R of the bendable region R_{F} was from 2.0 mm to 3.0 mm. At this time, the cover 43 (see FIG. 3) of the organic EL display panel was set to be on the inner side of the bend.

### Test Procedure

The organic EL panel was bent 200000 times at a bending speed 30 rpm at room temperature (about 25° C.) by alternately repeating a non-bent state (0°) in which the organic EL panel was not bent and a bent state (180°) in which the organic EL panel was bent.

### Comparative Example 2

An adhesive layer having thickness of 50 μm was provided on the back surface (back surface of the flexible display layer) of the flexible organic EL display panel obtained in the comparative example 1, and a support substrate (stainless steel plate, thickness: 30 μm, elastic modulus: about 193 GPa) was adhesively fixed via the adhesive layer. The entirety region (the entire organic EL display panel) including the display region D and the frame region N (the bendable region R_{B} and the non-bendable region R_{F}) was adhesively fixed between the support substrate and the organic EL display panel. The drop impact test and the bending test were performed in the same manner as described above using an organic EL display device (foldable display) including a layered body in which the support substrate was adhesively fixed to the entire back surface of the organic EL display panel. As a result, according to the organic EL display device of a comparative example 2, the bending test was passed, but the drop impact test was failed because a point defect caused by breakage of the TFT layer occurred. The reason why the organic EL display panel passed the bending test is considered as follows: the relatively thick adhesive layer was provided in the comparative example 2, and thus the adhesive layer slipped (the adhesive layer was deformed in the thickness direction), and breakage of the organic EL display panel due to bending was prevented.

### Comparative Example 3

In the same manner as in the comparative example 2 except that the adhesive layer having a thickness of 5 μm or less was used, the organic EL display device (foldable display) including the layered body in which the support substrate was adhesively fixed to the entire back surface of the organic EL display panel was manufactured, and the drop impact test and the bending test were performed in the same manner as described above. As a result, according to the organic EL display device of a comparative example 3, the drop impact test was passed, but the bending test was failed because a display defect caused by breakage of the TFT layer occurred.

### Comparative Example 4

An adhesive layer having a thickness of 50 μm and formed in a frame shape so as to overlap the frame region N of the organic EL display panel in a plan view was provided on the back surface (back surface of the flexible display layer) of the flexible organic EL display panel obtained in the comparative example 1, and the same support substrate as that of the comparative example 2 was adhesively fixed via the adhesive layer. Subsequently, an adhesive layer having a thickness of 50 μm was provided on the entire back surface of the support substrate, and a pseudo housing (formed of metal, hereinafter simply referred to as “housing”) having a pseudo hinge mechanism was adhesively fixed via the adhesive layer. The housing and the support substrate were adhesively fixed to each other in the entire region (entire organic EL display panel) including the display region D and the frame region N (the bendable region R_{B} and the non-bendable region R_{F}).

In a comparative example 4, the support substrate and the organic EL display panel are adhesively fixed to each other only in the frame region N (the entirety of the frame region N, the entire periphery along the peripheral edge of the frame region N), while they are not adhesively fixed to each other in the display region D. A gap having a thickness of about 50 μm (hereinafter referred to as “upper gap” in the examples) is formed between the support substrate and the organic EL display panel.

By using the organic EL display device obtained above (the foldable display, a layered body in which the support substrate was not adhesively fixed in the display region D of the back surface of the organic EL display panel), the drop impact test and the bending test were performed in the same manner as described above. As a result, according to the organic EL display device of a comparative example 4, the bending test was passed, but the drop impact test was failed because a point defect caused by breakage of the TFT layer occurred. Not that no improvement in the impact resistance was observed even when the thickness of the upper gap was increased to 1200 μm.

### Example 1

In the same manner as in the comparative example 4, the same support substrate as that of the comparative example 2 was adhesively fixed on the back surface of the flexible organic EL display panel via the adhesive layer having a frame shape along the periphery of the display region D so that the thickness of the upper gap was about 50 μm. Subsequently, a fixing member (a resin frame having a thickness of 300 μm) formed in a frame shape so as to overlap the frame region N of the organic EL display panel in a plan view was provided on the back surface of the support substrate, and the same housing as that of the comparative example 4 was adhesively fixed via the fixing member. Note that a double-sided adhesive tape was used to fix the support substrate and the housing to the fixing member.

In the example 1, in the display region D, not only the support substrate and the organic EL display panel are not adhesively fixed to each other, but also the support substrate and the housing are not adhesively fixed to each other, and a gap having a thickness of about 300 μm (hereinafter referred to as “lower gap” in the examples) is formed between the support substrate and the housing. As described above, in the example 1, in the display region D, the lower gap and the upper gap are formed on the back surface (lower face) and the front surface (upper face) of the support substrate, respectively, and the total thickness of the two gaps is about 350 μm.

By using the organic EL display device obtained above (the foldable display, the layered body in which the display panel and the support substrate were not fixed to each other and the gap was formed between the support substrate and the housing in the display region D), the drop impact test and the bending test were performed in the same manner as described above. As a result, according to the organic EL display device of the example 1, both the drop impact test and the bending test were passed. Thus, it was found that in the organic EL display device of the example 1, both the impact resistance against the large point impact and the flexibility of the display panel can be achieved. Specifically, by further providing the gap (lower gap) having the thickness of about 300 μm between the support substrate and the housing, the impact resistance was improved even when the total thickness of the gaps was 400 μm or less in the entire device.

### Effect

As described above, according to the organic EL display device 70a of the present embodiment, the following effects can be obtained.

As described above, in the organic EL display device such as the foldable display that is foldable, since it is necessary to maintain flexibility, the organic EL display panel includes only a flexible member, and in this respect, the followings are required to be improved.

(A) Impact resistance is poor.

(B) It is relatively difficult to keep the organic EL display panel in a flat shape due to occurrence of undulation, warping, or the like.

(C) Depending on a method or means for solving the problems (A) and (B), the flexibility of the organic EL display panel may not be maintained.

(1) Regarding the above points, in the organic EL display device 70a, the support substrate 50 is provided on the lower side of the flexible organic EL display panel 40. The support substrate 50 is formed of a single plate so as to cover the entire organic EL display panel 40 and a member being flexible but having a large elastic modulus (for example, about 193 GPa) is used, and thus the shape of the organic EL display panel 40 can be kept flat and the undulation can be prevented (the point (B) can be improved).

(2) In the organic EL display device 70a, in the display region D, the organic EL display panel 40 and the support substrate 50 are not fixed to each other, and the gap G defined by the support substrate 50 and the housing 60 is formed. Specifically, in the display region D, the adhesive layer or the like is not present between the organic EL display panel 40 and the support substrate 50, and the organic EL display panel 40 and the support substrate 50 can bend independently of each other. That is, even when there is a difference in the amount of deflection due to the difference in elastic modulus, the organic EL display panel 40 and the support substrate 50 are less likely to affect each other. Furthermore, there is a sufficient gap G that can be an air cushion on the lower side of the support substrate 50. As a result, even when the surface of the organic EL display panel 40 receives the large point impact such as the pen drop, the support substrate 50 can be gently and sufficiently bent, and thus, a local impact is less likely to occur, and the impact can be dispersed and alleviated (the point (A) can be improved). As a result, a crack is less likely to occur in the inorganic film constituting the TFT layer 20 of the organic EL display panel 40, and the occurrence of the display defect can be reduced.

(3) In the organic EL display device 70a, the flexibility of the organic EL display panel 40 is also maintained (the point (C) can be improved).

(4) Thus, in the organic EL display device 70a, both the impact resistance against the large point impact and the flexibility of the organic EL display panel 40 can be achieved (the points (A), (B), and (C) can be simultaneously solved).

(5) In addition, when any one of the above-described first to third modification examples is applied to the organic EL display device 70a, in the adhesive layer 48 provided between the organic EL display panel 40 and the support substrate 50, the pair of frame region openings 48b, 48c, and 48d are formed in the vicinity of the bendable region R_{B} including the bendable portion B which is the portion overlapping the frame region N in a plan view. In the frame region openings 48b, 48c, and 48d, the organic EL display panel 40 and the support substrate 50 are not adhesively fixed to each other, and thus even when there is a difference in the amount of deflection due to the difference in elastic modulus between the organic EL display panel 40 and the support substrate 50, the organic EL display panel 40 and the support substrate 50 are less likely to affect each other. Thus, the flexibility of the organic EL display panel 40 can be further improved. In this case, the adhesive layer 48 can be made relatively thin (for example, about 2 μm or more and about 50 μm or less).

### Second Embodiment

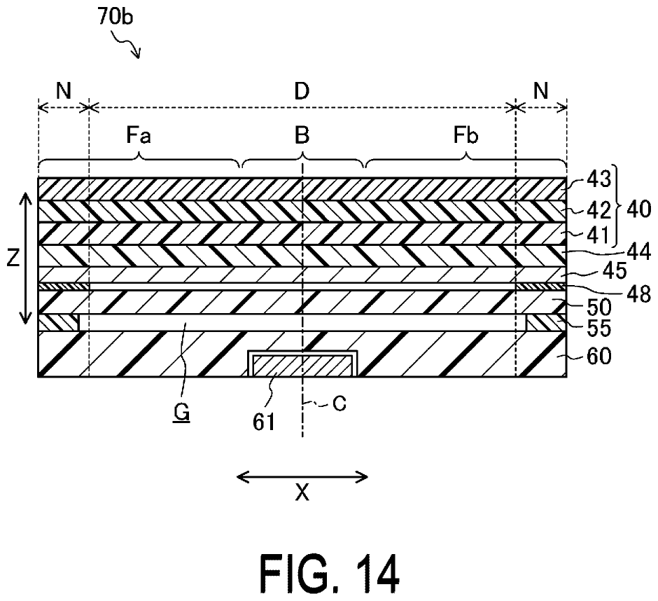

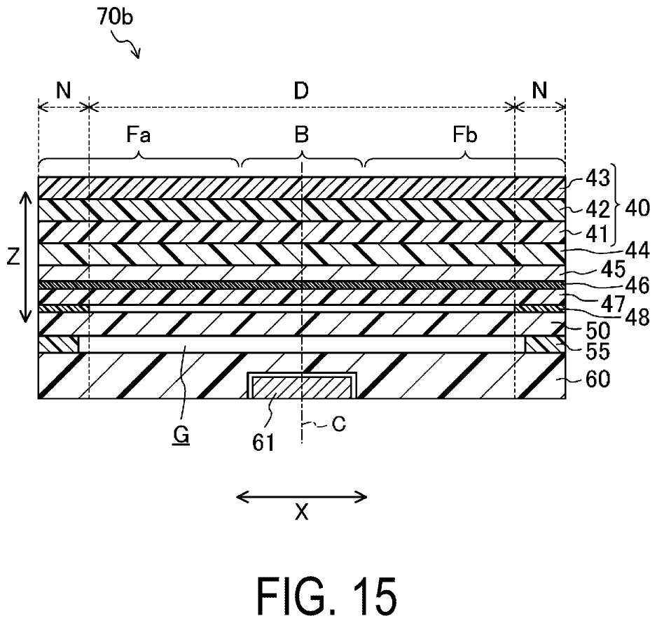

Next, a second embodiment of the disclosure will be described. FIG. 14 and FIG. 15 illustrate a second embodiment of the display device according to the disclosure. FIG. 14 is a cross-sectional view illustrating a deployed state of an organic EL display device 70b according to the present embodiment, and is a view corresponding to FIG. 3. FIG. 15 is a cross-sectional view illustrating the deployed state of a modification example of the organic EL display device 70b, and is a view corresponding to FIG. 3.

The entire configuration of the organic EL display device 70b is the same as the case of the first embodiment described above other than the configuration between the organic EL display panel 40 and the support substrate 50, and thus detailed description thereof will be omitted. Note that constituent portions similar to those in the first embodiment are denoted by the same reference signs, and a description thereof will be omitted.

As illustrated in FIG. 14, in the organic EL display device 70b, a metal film layer 45 is provided between the organic EL display panel 40 and the support substrate 50. The metal film layer 45 is disposed on the back surface of the organic EL display panel 40, and thus the point impact received by the surface of the organic EL display panel 40 is converted into a surface impact. The metal film layer 45 is preferably a member having a large elastic modulus (for example, about 193 GPa) such as a metal thin film, and is formed of, for example, a material containing at least one selected from stainless steel, titanium, aluminum, and copper. The thickness of the metal film layer 45 is, for example, 20 μm and more and 45 μm or less, and preferably 25 μm or more and 35 μm or less. The elastic modulus of the metal film layer 45 is, for example, 100 GPa or more and 210 GPa or less, and preferably 120 GPa or more and 200 GPa or less.

As illustrated in FIG. 14, in the organic EL display device 70b, the organic EL display panel 40 and the support substrate 50 are fixed to each other via the metal film layer 45 in the frame region N of the organic EL display panel 40.

Specifically, as illustrated in FIG. 14, an adhesive layer 44 is provided between the organic EL display panel 40 and the metal film layer 45, and the organic EL display panel 40 and the metal film layer 45 are adhesively fixed to each other via the adhesive layer 44. Examples of the adhesive layer 44 include the OCA, the adhesive tape, and the sponge cushion. From the viewpoint of flexibility, the adhesive layer 44 is preferably relatively thick and soft, and, for example, has a thickness of 15 μm or more and 100 μm or less and a shear modulus of 500 kPa or less at 25° C. The adhesive layer 44 may be provided on the entire surface of the organic EL display panel 40 or the metal film layer 45 (entire surface adhesion), or may be provided on at least a part thereof (partial adhesion). In addition, the adhesive layer 44 need not be provided (non-adhesion).

The metal film layer 45 may be fix to the support substrate 50 by adopting a method similar to the method of fixing the organic EL display panel 40 to the support substrate 50 in the organic EL display device 70a according to the first embodiment (including above-described first to third modification examples). Specifically, as illustrated in FIG. 14, the metal film layer 45 and the support substrate 50 are not fixed to each other in the region (preferably, the entirety thereof) overlapping the display region D in a plan view. In the region (preferably, the entirety thereof) overlapping the display region D in a plan view, it is sufficient that the metal film layer 45 and the support substrate 50 are simply not fixed to each other, and a gap need not be formed or may be formed between the metal film layer 45 and the support substrate 50.

### Modification Example of Second Embodiment

As illustrated in FIG. 15, in the organic EL display device 70b, a cushion layer (shock absorption layer) 47 may be provided between the metal film layer 45 and the support substrate 50. The cushion layer 47 is disposed on a lower side of the metal film layer 45 (on the back surface of the organic EL display panel 40), and thus an impact received by the surface of the organic EL display panel 40 is absorbed by the cushion layer 47.

The cushion layer 47 is formed of a single layer or a plurality of layers including at least one layer selected from a flexible resin film layer, a graphite sheet layer, and a foam layer (foam). A preferred form of the cushion layer 47 includes the flexible resin film layer. Examples of the flexible resin film layer include a urethane resin-based film and the like, and Young's modulus is preferably 1 GPa or less, and more preferably 100 MPa or less. The cushion layer 47 may be a layered body including, in addition to the flexible resin film layer, the graphite sheet layer and/or the foam layer. When the graphite sheet layer is present, a soaking effect of the organic EL display panel 40 is obtained. The thickness of the cushion layer 47 is, for example, 25 μm or more and 500 μm or less, and preferably 50 μm or more and 200 μm or less.

As illustrated in FIG. 15, in the modification example, the organic EL display panel 40 and the support substrate 50 are fixed to each other via the metal film layer 45 and the cushion layer 47 in the frame region N of the organic EL display panel 40.

Specifically, as illustrated in FIG. 15, an adhesive layer 46 is provided between the metal film layer 45 and the cushion layer 47, and the metal film layer 45 and the cushion layer 47 are adhesively fixed to each other via the adhesive layer 46. Examples of the adhesive layer 46 include the OCA, the adhesive tape, and the sponge cushion. From the viewpoint of flexibility, the adhesive layer 46 is preferably relatively thick and soft, and, for example, has a thickness of 15 μm or more and 50 μm or less and a shear modulus of 100 kPa or less at 25° C. The adhesive layer 46 may be provided on the entire surface of the metal film layer 45 or the cushion layer 47 (entire surface adhesion), or may be provided on at least a part thereof (partial adhesion). In addition, the adhesive layer 46 need not be provided, and the cushion layer 47 may be formed as a layered body further including the adhesive layer 46. In addition, the metal film layer 45 and the cushion layer 47 need not be adhesively fixed to each other.

The cushion layer 47 may be fix to the support substrate 50 by adopting a method similar to the method of fixing the organic EL display panel 40 to the support substrate 50 in the organic EL display device 70a according to the first embodiment (including the first to third modification examples). That is, as illustrated in FIG. 15, the cushion layer 47 and the support substrate 50 are not fixed to each other in the region (preferably, the entirety thereof) overlapping the display region D in a plan view. In the region (preferably, the entirety thereof) overlapping the display region D in a plan view, it is sufficient that the cushion layer 47 and the support substrate 50 are simply not fixed to each other, and a gap need not be formed or may be formed between the cushion layer 47 and the support substrate 50.

As described above, according to the organic EL display device 70b according to the present embodiment, the following effects can be obtained in addition to the above-described effects (1) to (5).

(6) In the organic EL display device 70b, the metal film layer 45 is provided on the lower side of the organic EL display panel 40, and the metal film layer 45 and the support substrate 50 are not fixed to each other in the region overlapping the display region D in a plan view. Thus, the point impact can be converted into the surface impact. As a result, the metal film layer 45 and the support substrate 50 are gently bent, and thus the impact resistance against the large point impact can be further improved.

(7) The organic EL display device 70b includes the metal film layer 45 having a high elastic modulus on the lower side of the organic EL display panel 40, and thus the undulation or the warping of the organic EL display panel 40 can be further prevented.

(8) In the organic EL display device 70b, even in a case where the thickness of the gap G between the support substrate 50 and the housing 60 is small, the impact resistance is as excellent as that of an organic EL display device (for example, the above-described organic EL display device 70a) that does not include the metal film layer 45. That is, in the organic EL display device 70b, the thickness of the gap G can be made small.

(9) In addition, when the above-described modification example is applied to the organic EL display device 70b, the cushion layer 47 serving as the impact absorption layer is provided on the lower side of the metal film layer 45, and the cushion layer 47 and the support substrate 50 are not fixed to each other in the region overlapping the display region D in a plan view. As a result, even when the large impact is applied, the impact applied to the support substrate 50 disposed on the lower side of the cushion layer 47 is alleviated. Thus, the impact resistance can be further improved. In this case, the thickness of the gap G can be further made small.

### Third Embodiment

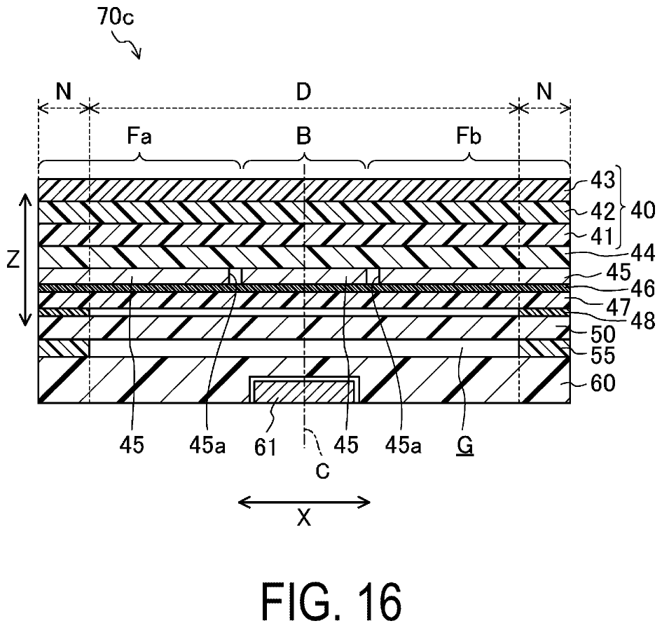

Next, a third embodiment of the disclosure will be described. FIG. 16 to FIG. 18 illustrate a third embodiment of the display device according to the disclosure. FIG. 16 is a cross-sectional view illustrating a deployed state of an organic EL display device 70c according to the present embodiment, and is a view corresponding to FIG. 3. FIG. 17 is an enlarged cross-sectional view illustrating a folded state in which the organic EL display device 70c is folded in the U-shape, and is a view corresponding to FIG. 5. FIG. 18 is an enlarged cross-sectional view illustrating a folded state in which the organic EL display device 70c is folded in the droplet shape, and is a view corresponding to FIG. 5.

The entire configuration of the organic EL display device 70c is the same as the case of the second embodiment described above other than the configuration of the metal film layer 45, and detailed description thereof will be omitted. Constituent portions similar to those in the first and the second embodiments are denoted by the same reference signs, and a description thereof will be omitted.

As illustrated in FIG. 16 to FIG. 18, in the organic EL display device 70c, the metal film layer 45 is provided between the organic EL display panel 40 and the support substrate 50 similarly to the organic EL display device 70b according to the second embodiment described above, but the organic EL display device 70c is different in that the metal film layer 45 includes openings. In FIG. 17 and FIG. 18, the adhesive layer 44 and 46 and the housing 60 are omitted.

Specifically, as illustrated in FIG. 16 to FIG. 18, the metal film layer 45 includes a pair of openings (hereinafter also referred to as “metal openings”) 45a and 45a formed in portions closer to the bendable portion B in the frame regions N and N provided in the peripheries of the pair of flat portions Fa and Fb, respectively. Each of the pair of metal openings 45a and 45a is formed in a slit shape extending along the bending axis C (direction Y) of the bendable portion B. Each of the metal openings 45a having the slit shape may be formed up to both ends in the direction Y, or may be formed up to the vicinity of both ends in the direction Y. In addition, each of the metal openings 45a is not limited to the slit shape linearly extending along the direction Y, and may be formed in an island shape (dotted line shape) along the direction Y.

As illustrated in FIG. 17, in the case where the bent shape of the organic EL display panel 40 is the U-shape, the pair of metal openings 45a and 45a are disposed at portions corresponding to the vicinity of the bendable portion B (bendable region R_{B}) in the pair of flat portions Fa and Fb (non-bendable region R_{F}), respectively. As illustrated in FIG. 18, in a case where the bent shape of the organic EL display panel 40 is a droplet shape, the pair of metal openings 45a and 45a are disposed at portions corresponding to the vicinities of inflection points of an outward bending region and an inward bending region in the pair of flat portions Fa and Fb, respectively. As illustrated in FIG. 16, the metal film layer 45 is divided (separated) into a plurality of parts (three parts in FIG. 16) by the pair of metal openings 45a and 45a, and the parts are disposed to be separated from each other. As a result, a decrease in flexibility of the organic EL display panel 40 due to the metal film layer 45 is suppressed.

As illustrated in FIG. 16 to FIG. 18, in the organic EL display device 70c, the cushion layer 47 (and the adhesive layer 46) is provided on the lower side of the metal film layer 45, but the cushion layer 47 (and the adhesive layer 46) need not be provided.

As described above, according to the organic EL display device 70c according to the present embodiment, the following effects can be obtained in addition to the above-described effects (1) to (9).

(10) In the organic EL display device 70c, the metal film layer 45 provided on the lower side of the organic EL display panel 40 includes the pair of metal openings 45a and 45a formed in the portions corresponding to the vicinity of the bendable region R_{B} in the non-bendable region R_{F}. Thus, the flexibility of the organic EL display panel 40 is further improved. In this case, even in a case where the adhesive layer 44 provided between the organic EL display panel 40 and the metal film layer 45 is thin (for example, about 5 μm or more and about 45 μm or less), flexibility can be ensured.

### Fourth Embodiment

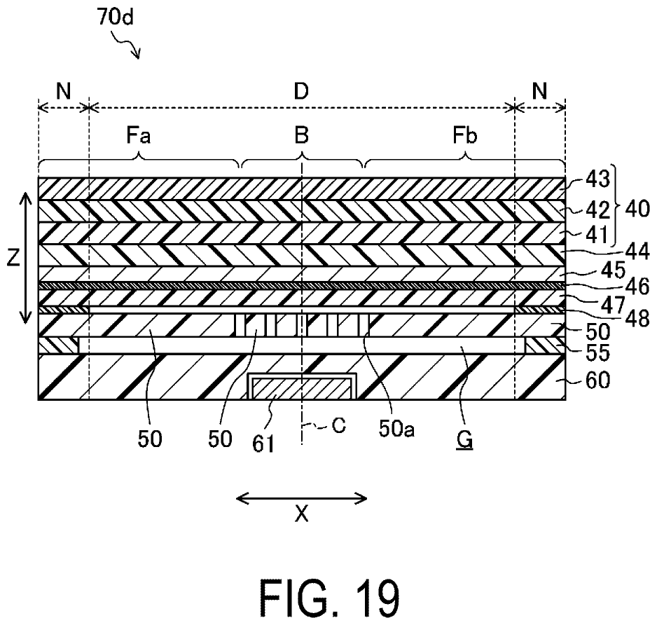

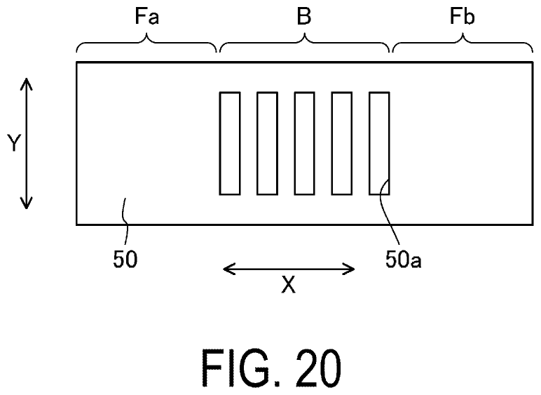

Next, a fourth embodiment of the disclosure will be described. FIG. 19 and FIG. 20 illustrate a fourth embodiment of a display device according to the disclosure. FIG. 19 is a cross-sectional view illustrating a deployed state of an organic EL display device 70d according to the present embodiment, and is a view corresponding to FIG. 3. FIG. 20 is a plan view illustrating a deployed state of the support substrate 50 constituting the organic EL display device 70d.

The entire configuration of the organic EL display device 70d is the same as that of the first to third embodiments described above other than the configuration of the support substrate 50, and thus detailed description thereof will be omitted. Note that constituent portions similar to those in the first to the third embodiments are denoted by the same reference signs, and a description thereof will be omitted.

As illustrated in FIG. 19 and FIG. 20, in the organic EL display device 70d, openings are formed in the support substrate 50. Specifically, the support substrate 50 includes at least one (five in FIG. 19 and FIG. 20) openings (hereinafter also referred to as “substrate openings”) 50a formed in a portion (bendable region R_{B} including the bendable portion B) overlapping the bendable portion B in a plan view. The substrate openings 50a communicate with (connected to) the gap G defined on the lower side of the support substrate 50.

In a case where the support substrate 50 is thin (for example, less than 100 μm (preferably 20 μm or more and 45 μm or less)) or in a case where the support substrate 50 is formed of the same material as the metal film layer 45, the substrate openings 50a may be formed in a shape of a plurality of (five in FIG. 20) slits so as to extend along the bending axis C (direction Y) of the bendable portion B up to the vicinities of both ends in the bending axis C direction as illustrated in FIG. 20. Each of the substrate openings 50a is not limited to the slit shape linearly extending along the direction Y, and may be formed in an island shape (dotted line shape) along the direction Y. In this case, as illustrated in FIG. 20, in the bendable portion B, the support substrate 50 is connected (not divided (separated)) in a direction (direction X) substantially orthogonal to the bending axis C direction outside both ends in the direction Y of each of the substrate openings 50a.

In addition, in the support substrate 50 including the substrate openings 50a, a portion overlapping the bendable portion B in a plan view may be formed in, for example, a slotted shape, a lattice shape, a chain shape, a living hinge shape (a lot shape), or the like.

On the other hand, in a case where the support substrate 50 is thick (for example, about 100 μm or more and about 200 μm or less), the substrate opening 50a may be formed as one opening over the entire portion overlapping the bendable portion B in a plan view. In this case, the support substrate 50 may be divided (separated) into two parts by the substrate opening 50a, and the two parts may be disposed to be separated from each other. In other words, the support substrates 50 and 50 may be disposed in portions corresponding to the flat portions Fa and Fb, respectively, of the organic EL display panel 40.

As illustrated in FIG. 19, in the organic EL display device 70d, the metal film layer 45 and the cushion layer 47 (further, the adhesive layers 44 and 46) are provided between the organic EL display panel 40 and the support substrate 50, but only the metal film layer 45 (and the adhesive layer 44) may be provided, and the metal film layer 45 and the cushion layer 47 (further, the adhesive layers 44 and 46) need not be provided. In addition, a cushion layer configured similarly to the cushion layer 47 may be provided on the lower side of the support substrate 50 in which the substrate openings 50a are formed.

As described above, according to the organic EL display device 70d according to the present embodiment, the following effects can be obtained in addition to the above-described effects (1) to (10).

(11) In the organic EL display device 70d, at least one substrate opening 50a is formed in the support substrate 50 in the portion overlapping the bendable portion B in a plan view, and thus even when the support substrate 50 is relatively thick (for example, about 100 μm or more and about 200 μm or less), the support substrate 50 can be slightly bent by the gap G present on the lower side of the substrate opening 50a and the support substrate 50. In the case where the support substrate 50 is thick, the undulation of the organic EL display panel 40 can be prevented.

### OTHER EMBODIMENTS

The configurations in the above-described embodiments can be appropriately combined and applied.

In each of the embodiments described above, the organic EL layer having a five-layer structure including the hole injection layer, the hole transport layer, the light-emitting layer, the electron transport layer, and the electron injection layer is exemplified, but the organic EL layer may have a three-layer structure including a hole injection-cum-transport layer, a light-emitting layer, and an electron transport-cum-injection layer, for example.

In each of the embodiments described above, the organic EL display device including the first electrode as an anode and the second electrode as a cathode is exemplified. The disclosure is also applicable to an organic EL display device in which the layered structure of the organic EL layer is reversed with the first electrode being a cathode and the second electrode being an anode.

In each of the embodiments described above, the organic EL display device in which the electrode of the TFT connected to the first electrode serves as the drain electrode is exemplified. However, the disclosure is also applicable to an organic EL display device in which the electrode of the TFT connected to the first electrode is referred to as the source electrode.

In addition, in each of the embodiments described above, the organic EL display device is exemplified and described as a display device. The disclosure is also applicable to a display device including a plurality of light-emitting elements that are driven by an electrical current. For example, the disclosure is applicable to a display device including quantum-dot light emitting diodes (QLEDs) that are light-emitting elements using a quantum dot-containing layer.

### INDUSTRIAL APPLICABILITY

As described above, the disclosure is useful for the flexible display device, particularly the foldable display.

1. A display device comprising:
a flexible display panel including
a display region including a pair of flat portions held in a flat manner and a bendable portion disposed between the pair of flat portions and held in a bendable manner and
a frame region provided in a periphery of the display region;
a support substrate supporting the display panel in a flat manner; and
a housing supporting the support substrate,
wherein in the display region, the display panel and the support substrate are not fixed to each other and a gap is formed between the support substrate and the housing,
a metal film layer is provided between the display panel and the support substrate, and
the metal film layer and the support substrate are not fixed to each other in a region overlapping the display region in a plan view.

2. The display device according to claim 1,
wherein the display panel and the support substrate are not fixed to each other in the entirety of the display region, and the gap is formed between the support substrate and the housing.

3. The display device according to claim 1,
wherein an adhesive layer is provided between the display panel and the support substrate along the entire periphery of the frame region, and
the display panel and the support substrate are adhesively fixed to each other via the adhesive layer.

4. The display device according to claim 3,
wherein the adhesive layer includes a pair of openings formed in a portion where a bendable region extending along the bendable portion and the frame region overlap each other in a plan view.

5. The display device according to claim 4,
wherein the pair of openings are formed in a slit shape extending along a bending axis of the bendable region.

6. The display device according to claim 3,
wherein the adhesive layer includes a pair of openings formed in portions closer to the bendable portion in the frame region provided in peripheries of the pair of flat portions, respectively, and
the pair of openings are formed in a slit shape extending along a bending axis of the bendable portion.

7. (canceled)

8. The display device according to claim 1,
wherein the metal film layer includes a pair of openings formed in portions closer to the bendable portions in the frame region provided in peripheries of the pair of flat portions, respectively, and
the pair of openings are formed in a slit shape extending along the bending axis of the bendable portion.

9. The display device according to claim 1,
wherein an adhesive layer is provided between the display panel and the metal film layer, and
the display panel and the metal film layer are adhesively fixed to each other via the adhesive layer.

10. The display device according to claim 1,
wherein the metal film layer is formed of a material containing at least one selected from stainless steel, titanium, aluminum, and copper.

11. The display device according to claim 1,
wherein a cushion layer is provided between the metal film layer and the support substrate, and
the cushion layer and the support substrate are not fixed to each other in a region overlapping the display region in a plan view.

12. The display device according to claim 11,
wherein an adhesive layer is provided between the metal film layer and the cushion layer, and
the metal film layer and the cushion layer are adhesively fixed to each other via the adhesive layer.

13. The display device according to claim 11,
wherein the cushion layer includes at least one layer selected from a flexible resin film layer, a graphite sheet layer, and a foam layer.

14. The display device according to claim 11, wherein Young's modulus of the cushion layer is 1 GPa or less.

15. The display device according to claim 1,
wherein a portion of the support substrate overlapping the bendable portion in a plan view is formed in a slotted shape, a lattice shape, a chain shape, or a living hinge shape.

16. The display device according to claim 1,
wherein the support substrate includes at least one opening formed in a portion overlapping the bendable portion in a plan view.

17. The display device according to claim 16,
wherein the at least one opening is formed in a slit shape extending along a bending axis of the bendable portion to vicinities of both ends of the support substrate in the bending axis direction.

18. The display device according to claim 1,
wherein the support substrate includes a flexible metal film.

19. The display device according to claim 18,
wherein the metal film is formed of a material containing at least one selected from stainless steel, titanium, aluminum, and copper.

20. The display device according to claim 18,
wherein the support substrate is formed of a layered body further including a flexible resin film.
